(19) United States
(12) Patent Application Publication
(10) Pub. No.: US 2023/0131991 A1
(43) Pub. Date: Apr. 27, 2023

(54) METHOD AND SYSTEM FOR ERROR CHECKING IN WIRELESS COMMUNICATIONS

(71) Applicant: ZEKU, INC., Palo Alto, CA (US)

(72) Inventor: Jian GU, San Diego, CA (US)

(21) Appl. No.: 18/146,330

(22) Filed: Dec. 23, 2022

Related U.S. Application Data
(63) Continuation of application No. PCT/US2021/019087, filed on Feb. 22, 2021.
(60) Provisional application No. 63/061,545, filed on Aug. 5, 2020.

(51) Int. Cl. H03M 13/09; H03M 13/41

(52) U.S. Cl. CPC H03M 13/09; H03M 13/413

(57) ABSTRACT

A method and system for error checking in a wireless communication are provided. The method includes: receiving a payload; determining a final decoding result of the payload, the final decoding result indicating a start state and an end state; determining whether the end state is identical to the start state based on a state circularity check; and determining to discard the final decoding result based on whether the end state is identical to the start state.

### CROSS-REFERENCE TO RELATED APPLICATION(S)

This application is a continuation of International Patent Application No. PCT/US2021/019087 filed on Feb. 22, 2021, which claims priority to U.S. Provisional Application No. 63/061,545 filed on Aug. 5, 2020. The entire contents of the prior applications are incorporated by reference herein by their entirety.

### BACKGROUND

In wireless communications, efficiency is a key concern. Although many factors can be weighed when determining whether a wireless communications system is efficient, bandwidth usage is particularly important. This is because bandwidth is a limited resource, but the traffic transmitted on the bandwidth is ever-increasing. Due to this dynamic, it is desirable to have the available bandwidth used efficiently for the transmission of signals.

For example, a potential opportunity to improve efficiency is to reduce the use of tail bits. Tail bits are used in wireless transmission techniques to help with error detection. However, tails bits are commonly viewed as overhead. To address this overhead issue, channel coding techniques such as tail biting channel coding are used because it does not require transmission of tail bits and thus improves transmission efficiency. Such techniques are widely used in tail-biting convolutional code and tail-biting turbo code.

### SUMMARY

The disclosure relates to wireless communication technologies, and in particular to error checking techniques in wireless communications, and more specifically to a method for error checking in a wireless communication and a system.

In a first aspect, the embodiments of the disclosure provide a method for error checking in a wireless communication, which may include the following operations.

A payload is received.

A final decoding result of the payload is determined. Herein, the final decoding result indicates a start state and an end state.

It is determined whether the end state is identical to the start state based on a state circularity check.

It is determined to discard the final decoding result based on whether the end state is identical to the start state.

In a second aspect, the embodiments of the disclosure further provide a method, which may include the following operations.

A payload is received.

A final decoding result of the payload is determined. Herein, the final decoding result indicates a start state and an end state. Herein, the final decoding result is determined, which includes that the payload is decoded.

It is determined whether the end state is identical to the start state based on a state circularity check.

An error check of the final decoding result is performed.

It is determined to discard the final decoding result based on (1) whether the end state is identical to the start state or (2) the error check.

In a third aspect, the embodiments of the disclosure further provide a system, which may include a receiver and a processor.

The receiver is operable to receive a payload.

The processor is configured to determine a final decoding result of the payload, herein, the final decoding result indicates a start state and an end state; determine whether the end state is identical to the start state based on a state circularity check; and determine to discard the final decoding result based on whether the end state is identical to the start state.

### BRIEF DESCRIPTION OF THE DRAWINGS

The present embodiments are illustrated by way of examples and are not intended to be limited by the figures in the accompanying drawings.

FIG. 1 illustrates a high level block diagram of a system with a state circularity check.

FIG. 2A illustrates a high level block diagram of an exemplary tail biting decoder with the state circularity check.

FIG. 2B illustrates a high level block diagram of another exemplary tail biting decoder with the state circularity check.

FIG. 3 illustrates an example of a trellis of Viterbi decoding for trail biting convolutional code.

FIG. 4 illustrates a flowchart of an exemplary method for performing a state circularity check.

FIG. 5 is a block diagram illustrating a diagrammatic representation of a machine in the example form of a computer system operable to perform aspects of the disclosed technology.

### DETAILED DESCRIPTION

The signals that are transmitted in wireless communications regularly experience interference. The interference causes errors in the signal, which can result in significant performance degradation. To prevent such degradation, wireless communications systems employ encoders and decoders at transmitters and receivers, respectively. Decoders help with detecting an error and correcting the error. If, however, the decoder is unable to correct the error but able to detect error, the decoder can discard the decoding result.

In general, undetected errors cause drastic degradation that reverberates throughout the wireless communications system. For example, an undetected error in the control channel of a wireless communications systems can trigger a wrong status in the receiver or transmitter. An undetected error in a traffic channel can cause retransmission of a larger packet in a higher layer of the communications stack. As such, the system will experience higher latency and lower transmission efficiency. As such, decoders can be tasked with error detection and error resolution. A common decoder is the tail-biting Viterbi or the turbo decoder.

Additional error checking methods include adding a cyclic redundancy check (CRC) bit, using a decoding path metric in the decoder to detect an error, and using a validness check for payload field to detect an error. CRC bits are generally added to the information bit before tail-biting convolutional coding or turbo coding. CRC bits are fixed length check values that are attached to packets. Once the packets are decoded, the CRC bits are used to determine whether the CRC check passes or not. Whether a CRC passes or not can be based on, for example, techniques applied to the received data to determine whether the remainder (e.g., obtained by dividing the received data by a polynomial) is zero or other known values or not. If the CRC check results do match the initial value(s), the likelihood of error having occurred is low. Conversely, if the values do not match, the decoding is considered a failure.

The decoding path metric technique compares a Viterbi decoder metric with a threshold value. Viterbi metric includes, for example, largest survival path metric and/or path metric difference between the state with the largest survival path and the state with the smallest path metric. In some cases, if the path metric is larger than the threshold, the decoding result is considered valid. Otherwise, the decoding result is considered a failure. The payload field validness check technique includes checking, by a receiver of a signal, whether the combination of values of multiple fields is allowed by a standard definition or not. If the combination is not allowed, the decoding is a failure, and thus, discarded. If the combination is allowed, the decoding is correct. In some cases, all three error checking methods can be used in combination or individually.

However, these and other error checking techniques have drawbacks that burden a wireless communication system. In particular, there are two significant issues with the above-mentioned techniques: significant overhead and poor efficiency. For instance, adding CRC bits is additional overhead that uses limited bandwidth in wireless communication. This issue can be compounded because the more CRC bits are added, the better the error detection. However, the transmission efficiency is reduced. In other words, in wireless communications, one of the primary concerns is to effectively use each transmission (e.g., bandwidth) to carry as much user traffic as possible. In a case where multiple CRC bits have to be added, the ability to carry user traffic is reduced; and thereby, burdens the system.

Another issue is the poor error detection performance of techniques such as the path metric and the validness check. For example, the efficacy of the path metric technique is largely reliant on the threshold value. The threshold value, in some cases, can be preprogrammed and/or static. Thus, the threshold value may not be adaptive to changing circumstances, which in turn, can results in poor accuracy. Similarly, the parameters may not be adapted to different circumstances (e.g., environmental interference), and thus, the efficacy of the technique will be reduced. In addition, other issues arise when error detection is not correctly done in an iterative decoder such as increased power consumption, increased use of computing power, and others. As such, the limited resources used in wireless communications are not efficiently used.

Introduced here, therefore, is at least one technique for improving error detection for tailing biting coded communications. The at least one technique can improve error detection irrespective of the existence or number of CRC bits, and/or usage of other error detection techniques. The technique includes determining whether a decoding result is correct by comparing the start state and end state of a survivor path of tail-biting convolutional decoding such as the Viterbi algorithm. Due to the usage of circular trellis in tail-biting Viterbi decoding techniques, the start state and end state of the decoder output bit in the survivor path should be the same. Thus, if the start state and end state are not the same, the decoding result is incorrect and should be discarded. For instance, at an initial stage, the state metrics can be initialized to zero, and the start state can be “00”. At a subsequent stage(s), the start state can be parsed through a Viterbi decoder, and the path metric can be calculated, and the final survivor path can be determined. After which, a circularity check can be performed to determine whether the start state and end state of decoding output are the same. Additional error checks can also be performed to further validate the decoding result.

In the following description, the examples of a system capable of wireless communications (e.g., mobile device, base station) is used, for illustrative purposes only, to explain various aspects of the techniques. For example, a cellular phone can apply a circularity check to determine whether a decoding result is correct. Note, however, the techniques disclosed here are not limited to applicability to terminal devices, receivers, or to any other particular kind of devices. Other devices, for example, electronic devices or systems (e.g., base stations) may adapt the techniques in a similar manner.

Further, note that while the techniques introduced here are described in the context of wireless communication such as a 4G or 5G core network, these techniques are not necessarily limited in applicability to any particular wireless network, nor even to wireless telecommunications. Hence, the techniques introduced here are potentially applicable in technology areas beyond those described herein.

The sequences of steps performed in any of the processes described here are exemplary. However, unless contrary to physical possibility, the steps may be performed in various sequences and combinations. For example, steps could be added to, or removed from, the processes described here. Similarly, steps could be replaced or reordered. Thus, descriptions of any processes are intended to be open-ended.

Moreover, the technology can be embodied using special-purpose hardware (e.g., circuitry), programmable circuitry appropriately programmed with software and/or firmware, or a combination of special-purpose hardware and programmable circuitry. Accordingly, embodiments may include a machine-readable medium having instructions that may be used to program a computing device (e.g., a base station or a network-connected computer server) to examine wireless communications packets, identify elements included in the packets, apply a circularity check to determine an appropriate action, and perform the appropriate action.

The term “module” refers broadly to software components, hardware components, and/or firmware components. Modules are typically functional components that can generate useful data or other output(s) based on specified input(s). A module may be self-contained. A computer program may include one or more modules. Thus, a computer program may include multiple modules responsible for completing different tasks or a single module responsible for completing all tasks.

### Circularity Check Overview

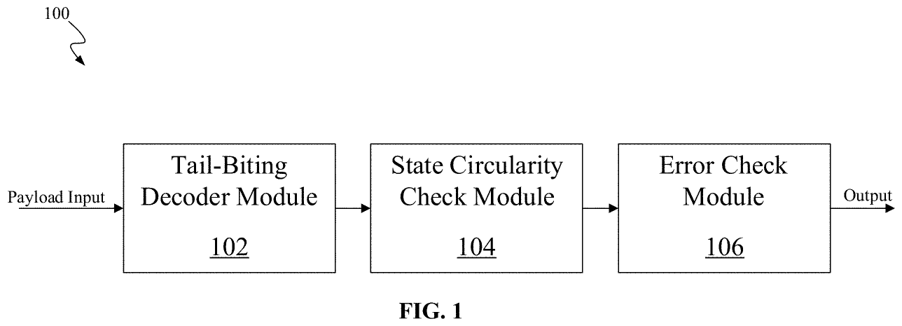

FIG. 1 illustrates a high level block diagram of a system 100 with a state circularity check. System 100 includes tail-biting decoder module 102, state circularity check module 104, and error check module 106. In FIG. 1 and as mentioned above, although the components are designated as modules, these components can be implemented as hardware or software at a device (e.g., a cell phone) or network. Further, the modules can be combined into a single piece of hardware or segmented into more than three modules. In other words, the illustration in FIG. 1 is not the only way the system 100 can be implemented.

Tail-biting decoder module 102 receives an input illustrated as the payload input. The payload input can be, for example, packets from a wireless transmission (e.g., signal). For instance, the payload input can be packets from a physical downlink control channel (PDCCH) signal. In another example, the payload input can be from a physical broadcast channel (PBCH). In another example, the payload input can be from a physical uplink control channel (PUCCH). The payload, moreover, can consist of one or more packets. The one or more packets can be linearly input into the tail-biting decoder module 102 or in any other manner.

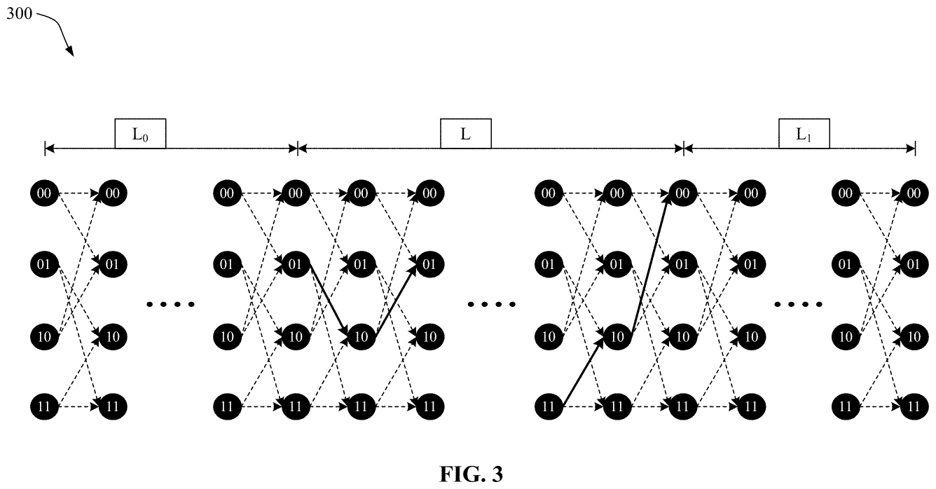

The tail-biting decoder module 102 can apply decoding (e.g., convolutional) algorithms such as Viterbi algorithms. The tail-biting decoder module 102 determines the best path in a trellis under the constraint that the start state and end state are identical. In this context, a trellis is, for example, a graph whose states are ordered into vertical segments of time with each state at each time segment connected to a at least one state at an earlier and at least one state a later time. An example of a trellis is depicted in FIG. 3, along with further description.

As such, the tail-biting decoder module 102 can determine a path within a trellis for packets. In some cases, the tail-biting decoder module 102 can determine every path in which the start state and end state of a decoding output are identical. From these paths, the tail-biting decoder module 102 can further determine which path is the best, which can be called the survival path. Whether a path is the best can be dependent on factors such as the path metric or others.

The circular nature, where the start state and end state are identical, of the convolutional algorithm applied by the tail-biting decoder module 102 can be used by the state circularity check module 104. Traditionally, as mentioned above, a CRC bit is added to a packet. The CRC bit, after decoding, indicates whether an error has occurred based on if the CRC check passes or not. However, due the circular nature of tail-biting convolutional decoding (e.g., Viterbi algorithms), the state circularity check module 104 can be used to determine whether the start state and end state of decoding output are identical, irrespective of the presence of a CRC bit.

The state circularity check module 104 compares the start state and end state of a decoding output to determine whether the result from the tail-biting decoder module is correct. The result is, for example, the survival path. The survival path can indicate the start state and end state. The state circularity check module 104 can, using the result (e.g., survival path), to compare the two states. If the end state is not identical to the start state, the state circularity check module 104 can determine to discard the decoding result. If the two states are identical, the state circularity check module 104 can determine that the decoding result is valid.

For example, the result from the tail-biting decoder module 102 can be a survival path with a start state of “00” and an end state of “01”. The state circularity check module 104 can, upon receipt of the survival path, compare the two states and determine that they are not identical. Due to this, the state circularity check module 104 can determine to discard the survival path. In another example, the survival path can indicate a start state of “00” and an end state of “00”. In this case, the state circularity check module 104 can determine that the result is valid.

In some embodiments, after the state circularity check module 104, the system 100 can apply one or more other error checking techniques at the error check module 106. If the state circularity check module 104 determines that the survival path is not valid, prior to discarding the survival path, the error check module 106 is skipped. Similarly, if the state circularity check module 104 determines that the survival is valid, the survival path can be transmitted to the error check module 106.

The error check module 106 can apply various error checks as described above, such as, for example, a CRC bit check, path metric check, and/or validness check. The output from the error check module 106 can indicate whether the system 100 should discard the result of tail-biting decoder module 102 or not. For example, the error check module 106 can apply the CRC bit check. By doing so, the error check module 106 can determine that the CRC bit after decoding is not identical to the pre-decoding value. And, thus, the result can be discarded.

In some embodiments, the error check module 106 is optional. In other words, only the state circularity check module 104 can be applied to check the validity of the result from the tail-biting decoder module 102. In some cases, error check module 106 can be performed before the state circularity check module 104. In some embodiments, the error check module 106 and state circularity check module 104 can operate in parallel. For example, the output from the tail-biting decoder module 102 can be input into both the error check module 106 and state circularity check module 104 simultaneously. In which case, if either the state circularity check module 104 or the error check module 106 determines an error, the result can be discarded.

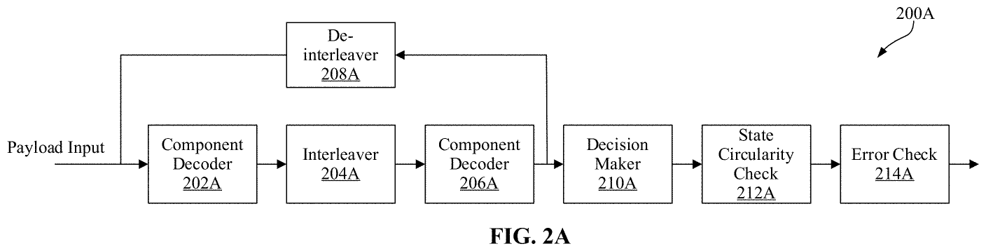

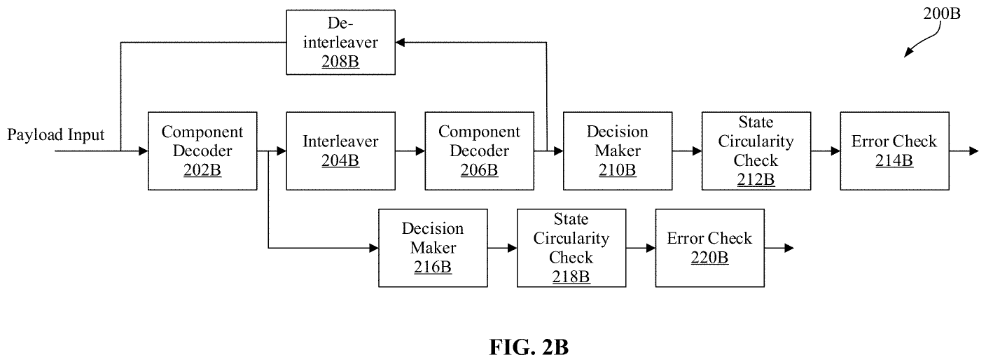

FIG. 2A illustrates a high level block diagram 200A of an exemplary tail biting turbo decoder with the state circularity check. The diagram 200A includes various components that provide details into the components of system 100 in FIG. 1. State circularity check 212A and error check 214A are similar to the state circularity check module 104 and error check module 106, respectively. The other components of diagram 200A, 202A, 204A, 206A, 208A, and 210A, can be components of the tail-biting decoder module 102 in FIG. 1.

There are different kinds of decoding algorithms that can be applied by component decoder 202A and 206A. For instance, maximum a posteriori (MAP) techniques, logarithmic maximum a posteriori (LOG-MAP) techniques, maximum logarithmic maximum a posteriori (MAX-LOG-MAP) techniques, and/or soft output Viterbi algorithms (SOVA). The interleaver 204A can randomize the sequence prior to input into the component decoder 206A, and de-interleaver 208A.

For example, component decoder 202A can output extrinsic information regarding one or more time segments of a trellis to the component decoder 206A. The decision maker 210A can output the decoding result to the state circularity check 212A to determine whether the result from the component decoder 206A is valid. If the results are not identical to the start value, the state circularity check 212A can determine to do another iteration. If, however, a maximum number of iterations have been reached, the result can be discarded.

For example, component decoder 202A can outputs extrinsic information for L₀+L₁+L information bits to component decoder 206A. At each iteration, decision maker 210A can output a value denoted as \hat{d}ₙ, n=1, . . . , L₀+L₁+L. Subsequently, the state circularity check 212A can determine if \hat{d}ₙ≠\hat{d}_{n+L}, for any n=L₀−m+1, . . . , L₀, the decoding result, \hat{d}ₙ, n=L₀+1, . . . , L₀+L, is wrong. Further, if the error is detected by other error checking techniques (e.g., applied by error check 214A), this decoding result \hat{d}ₙ, n=L₀+1, . . . , L₀+L is also wrong.

If an error is not detected by the state circularity check 212A and/or the error check 214A, the decoding result is considered as a success and decoding iteration stops. If, however, an error is detected and decoding iteration doesn't reach its maximum number, another decoding iteration can be performed. However, if the decoding iteration is at or beyond the maximum number, the iterating stops, and final failed decoding result is discarded.

FIG. 2B illustrates a high level block diagram 200B of another exemplary tail biting turbo decoder with the state circularity check. Diagram 200B includes similar components as in diagram 200A for FIG. 2A. Similar designations may indicate similar functionality. For example, component decoder 202B may function similarly to component decoder 202A in FIG. 2A. Diagram 200B further includes decision maker 216B, state circularity check 218B, and error check 220B. These components have similar functions to components 210B, 212B, and 214B, respectively. However, decision maker 216B, state circularity check 218B, and error check 220B, use the output from component decoder 202B.

In FIG. 2B, component decoder 202B can output extrinsic information for L₀+L₁+L information bits to component decoder 206B. At each half iteration (e.g., after component decoder 202B and prior to component decoder 206B), the output from the decision marker 216B can be denoted as \hat{d}ₙ, n=1, . . . , L₀+L₁+L. If \hat{d}ₙ≠\hat{d}_{n+L}, for any n=L₀−m+1, . . . , L₀, the decoding result, \hat{d}ₙ, n=L₀+1, . . . , L₀++L, is wrong. If an error is detected by the error check 220B, this decoding result \hat{d}ₙ, n=L₀+1, . . . , L₀+L is also wrong. If an error is not detected, the decoding result is considered as success and decoding iteration stops. If an error is detected and the decoding iteration has not reached its maximum number, another half decoding iteration can occur. If the maximum number has been reached, the decoding iteration stops, and final failed decoding result is discarded. The full iteration, including component decoder 206B, can occur as described in conjunction with FIG. 2A.

### Trellis Example

FIG. 3 illustrates an example of a trellis 300 of Viterbi decoding for tail biting convolutional code or decoder for tail-biting turbo code. The trellis 300 contains three stages: L₀, L, and L₁. L is the PDCCH payload length, L₀ is the preparation length, and L₁+L is the trace-back length. Initially, all the metrics can be initialized to 0. For instance, s₀(n)=0, n=0, . . . , 2^{K}−1, where the number of total states is 2^{K}.

Subsequently, the decoding can start from an information bit, denoted as Lₛₜₐᵣₜ, where 0≤Lₛₜₐᵣₜ≤L−1. As mentioned above, the decoding can include determining a survival path. The survival path can include several metrics, such as the path metric. The decoder (e.g., tail-biting decoder module 102) can calculate the path metric for the information bit, Lₛₜₐᵣₜ, for all possible states within the trellis 300. Further, the decoder can perform an add-compare selection (ACS) for s₁(n), n=0, . . . , 2^{K}−1, the state metric of state n in stage 1, denoted by,

$${s}_{1} ( n ) = max \{ \begin{matrix}{s}_{0} ( ⌊ n / 2 ⌋ ) + {\sum }_{q = 1}^{Q} ( 1 - 2 {a}_{q} ( ⌊ n / 2 ⌋ , n \%2 ) * {y}_{{L}_{start} , q} ) , \\ {s}_{0} ( ⌊ n / 2 ⌋ + {2}^{K - 1} ) + {\sum }_{q = 1}^{Q} ( 1 - 2 {a}_{q} ( ⌊ n / 2 ⌋ + {2}^{K - 1} , n \%2 ) ) * {y}_{{L}_{start} , q}\end{matrix} \} ,$$

Where [symbol] x [symbol] is largest integer smaller than x, % is mod, Q is 1 over coding rate (1/R), y_{L}_{ₛₜₐᵣₜ}_{,q} is the received log-likelihood ratio (LLR) of the q-th coded bit of information bit Lₛₜₐᵣₜ. The selected path is called the survivor path, as mentioned above. The survivor path can be denoted by sₗ(n) and saved in memory.

In stage l, where l=1, . . . , L₀+L₁+L, the decoder decoded from bit (Lₛₜₐᵣₜ+l−1)% L, where 0≤Lₛₜₐᵣₜ≤L−1. Again, the path metric for bit (Lₛₜₐᵣₜ+l−1)% L for all states is determined and ACS is performed for sₗ(n), n=0, . . . , 2^{K}−1, where

$${s}_{l} ( n ) = max \{ \begin{matrix}{s}_{l - 1} ( n ≫ 1 ) + {\sum }_{q = 1}^{Q} ( 1 - 2 {a}_{q} ( n ≫ 1 , n \%2 ) * {y}_{{L}_{start} + l - 1 , q} ) , \\ {s}_{l - 1} ( n ≫ 1 + {2}^{K - 1} ) + {\sum }_{q = 1}^{Q} ( 1 - 2 {a}_{q} ( n ≫ 1 + {2}^{K - 1} , n \%2 ) ) * {y}_{{L}_{start} + l - 1 , q}\end{matrix} \} .$$

Subsequently, all sₗ(n) can be saved in memory. After stage L₀+L₁+L is done, a path called final decoding survivor path is the path with largest state metric among all survivor paths at stage L₀+L₁+L. Bit L₀+1 to L₀+L in the final decoding survivor path is the decoding output.

After the final survivor path is determined, the state circularity check can be performed. Optionally, other error checks such as the CRC check, path metric check, and/or payload field validness check can be performed as well. In the state circularity check, if the state of the final decoding survivor path at state L₀ is not identical to the state of the final decoding survival path at state L₀+L, the decoding result is wrong and discarded. Subsequently, if other error checks (e.g., CRC) are performed and fail, the decoding result is discarded. Conversely, if the state of the final decoding survivor path at state L₀ is identical to the state of the final decoding survival path at state L₀+L, the decoding result is a success.

In other words, in trellis 300, if the start state is “00”, the decoder can determine the multiple ways that the end state can also be “00” at the end of segment L. In trellis 300, for example, there may be ten different paths in which the start state and end state are “00” in between L₀ and L. From these ten paths, the decoder can determine one path that is best based on state metrics. The best path is then selected and is designated as the final survival path. The state circularity check can, based on the final survival path, determine whether the start state and end state are identical. If they are, the decoding is a success. If not, the decoding is a failure and the final survival path is discarded. Additionally, other error check can also be performed.

### Example Methodology

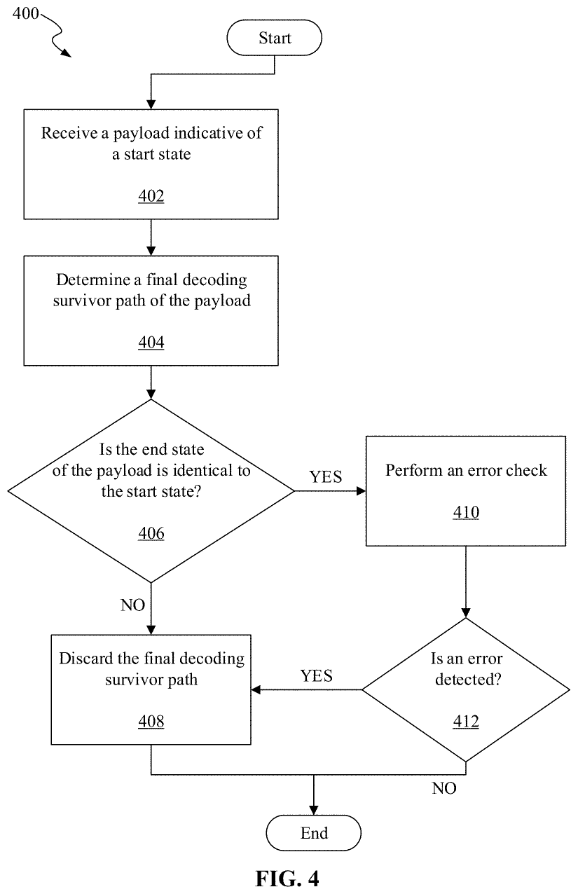

FIG. 4 illustrates a flowchart 400 of an exemplary method for performing a state circularity check. The method illustrated in flowchart 400 includes blocks 402, 404, 406, and 408. Further, the flowchart 400 can optionally include blocks 410 and 412. The flowchart 400 can be implemented by any device capable of wireless communications such as a mobile device (e.g., an iPhone). The device can include a receiver to receiver payloads (e.g., packets) from another wireless communications device such as a base station. The device can also include a processor to perform at least some of the techniques described herein.

At block 402, a device can receive a payload. The payload can be, for example, received from any tail-biting coded channels. At block 404, the device can determine a final decoding result of the payload. The final decoding result can indicate the start state and end state. In some embodiments, determining the final decoding result can include decoding the payload according to the Viterbi decoding techniques. In some embodiments, other algorithms such as MAP, LOG-MAP, MAX-LOG-MAP, and/or SOVA can be used to decode the payload.

At block 406, the device can determine whether the start state and end state are identical. If the two states are not identical, the final decoding result can be discarded. If the two states are identical, the decoding results, the final decoding result, is a success. In some embodiments, further error checks can be performed, as block 410. For example, if the payload includes one or more CRC bits, a CRC check can be performed. In another example, a path metric check can be performed. If the path metric of the survival path surpasses a threshold, the result can be invalid. In yet another example, a payload field validness check can be performed, in which if the payload includes an invalid field combination, the result can be invalid. In some cases, more than one of these error checks can be performed. If the error check(s) indicate an error, the final decoding result can be discarded. If an error is not detected, the final decoding result is a success. In some embodiments, as mentioned above, blocks 410 and 412 can be omitted. Thus, if the start state and end state are identical, the decoding is a success. As such, in some embodiments, the device can determine whether to discard the final decoding result based on (1) whether the end state is identical to the start state or (2) the error check.

### Example Computing System

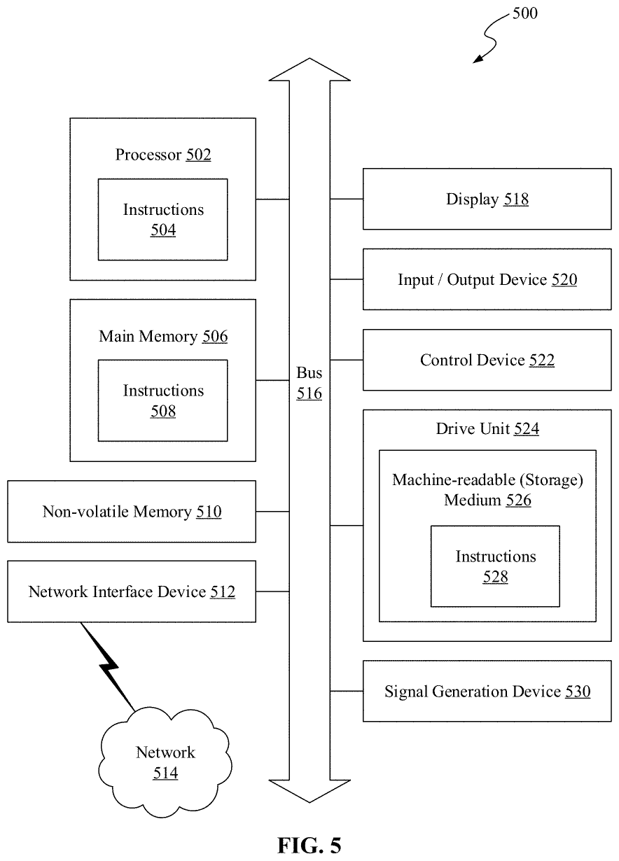

FIG. 5 is a block diagram illustrating a diagrammatic representation of a machine in the example form of a computer system operable to perform aspects of the disclosed technology. For example, processing system 500 may be an example implementation of a network node or terminal device that may implement the techniques introduced above. At least a portion of the processing system 500 may be included in an electronic device (e.g., a computer server) that supports one or more CPNs and/or one or more UPNs. The processing system 500 may include one or more processors 502, main memory 506, non-volatile memory 510, network adapter 512 (e.g., network interfaces), display 518, input/output devices 520, control device 522 (e.g., keyboard and pointing devices), drive unit 524 including a storage medium 526, and signal generation device 530 that are communicatively connected to a bus 516. The bus 516 represents any one or more separate physical buses, point to point connections, or any combination thereof, connected by appropriate bridges, adapters, or controllers. The bus 516, therefore, can include, for example, a system bus, a Peripheral Component Interconnect (PCI) bus or PCI-Express bus, a HyperTransport or industry standard architecture (ISA) bus, a small computer system interface (SCSI) bus, any version of a universal serial bus (USB), IIC (I2C) bus, or an Institute of Electrical and Electronics Engineers (IEEE) standard 1394 bus, also called “Firewire.” A bus may also be responsible for relaying data packets (e.g., via full or half duplex wires) between components of a network appliance, such as a switching engine, network port(s), tool port(s), etc.

In various embodiments, the processing system 500 operates as a standalone device, although the processing system 500 may be connected (e.g., wired or wirelessly) to other devices. For example, the processing system 500 may include a terminal that is coupled directly to a network appliance. As another example, the processing system 500 may be wirelessly coupled to the network appliance.

In various embodiments, the processing system 500 may be a server computer, a client computer, a personal computer (PC), a user device, a tablet PC, a laptop computer, a personal digital assistant (PDA), a cellular telephone, an iPhone, an iPad, a Blackberry, a processor, a telephone, a web appliance, a network router, switch or bridge, a console, a hand-held console, a (hand-held) gaming device, a music player, any portable, mobile, hand-held device, or any machine capable of executing a set of instructions (sequential or otherwise) that specify actions to be taken by the processing system 500.

While the main memory 506, non-volatile memory 510, and storage medium 526 (also called a “machine-readable medium) are shown to be a single medium, the term “machine-readable medium” and “storage medium” should be taken to include a single medium or multiple media (e.g., a centralized or distributed database, and/or associated caches and servers) that store one or more sets of instructions 528. The term “machine-readable medium” and “storage medium” shall also be taken to include any medium that is capable of storing, encoding, or carrying a set of instructions for execution by the processing system 500 and that cause the processing system 500 to perform any one or more of the methodologies of the presently disclosed embodiments.

In general, the routines that are executed to implement the technology disclosed above may be implemented as part of an operating system or an application, component, program, object, module, or sequence of instructions (collectively referred to as “computer programs”). The computer programs typically comprise one or more instructions (e.g., instructions 504, 508, 528) set at various times in various memory and storage devices in a computer, and that, when read and executed by one or more processing units or processors 502, cause the processing system 500 to perform operations to execute elements involving the various aspects of the above disclosure.

Moreover, while embodiments have been described in the context of fully functioning computers, computer systems and/or other devices, those skilled in the art will appreciate that the various embodiments are capable of being distributed as a program product in a variety of forms, and that the disclosure applies equally regardless of the particular type of machine or computer-readable media used to actually effect the distribution.

Further examples of machine-readable storage media, machine-readable media, or computer-readable (storage) media include recordable type media such as volatile and non-volatile memory devices 510, floppy and other removable disks, hard disk drives, optical disks (e.g., Compact Disk Read-Only Memory (CD ROMS), Digital Versatile Disks (DVDs)), and transmission type media such as digital and analog communication links.

The network adapter 512 enables the processing system 500 to mediate data in a network 514 with an entity that is external to the processing system 500, such as a network appliance, through any known and/or convenient communications protocol supported by the processing system 500 and the external entity. The network adapter 512 can include one or more of a network adaptor card, a wireless network interface card, a router, an access point, a wireless router, a switch, a multilayer switch, a protocol converter, a gateway, a bridge, bridge router, a hub, a digital media receiver, and/or a repeater.

The network adapter 512 can include a firewall which can, in some embodiments, govern and/or manage permission to access/proxy data in a computer network, and track varying levels of trust between different machines and/or applications. The firewall can be any number of modules having any combination of hardware and/or software components able to enforce a predetermined set of access rights between a particular set of machines and applications, machines and machines, and/or applications and applications, for example, to regulate the flow of traffic and resource sharing between these varying entities. The firewall may additionally manage and/or have access to an access control list which details permissions including for example, the access and operation rights of an object by an individual, a machine, and/or an application, and the circumstances under which the permission rights stand.

Other network security functions can be performed or included in the functions of the firewall, including intrusion prevention, intrusion detection, next-generation firewall, personal firewall, etc.

As indicated above, the techniques introduced here implemented by, for example, programmable circuitry (e.g., one or more microprocessors), programmed with software and/or firmware, entirely in special-purpose hardwired (i.e., non-programmable) circuitry, or in a combination of such forms. Special-purpose circuitry can be in the form of, for example, one or more application-specific integrated circuits (ASICs), programmable logic devices (PLDs), field-programmable gate arrays (FPGAs), etc.

Note that any of the embodiments described above can be combined with another embodiment, except to the extent that it may be stated otherwise above or to the extent that any such embodiments might be mutually exclusive in function and/or structure.

### CONCLUSION

The embodiments set forth herein represent the necessary information to enable those skilled in the art to practice the embodiments and illustrate the best mode of practicing the embodiments. Upon reading the description in light of the accompanying figures, those skilled in the art will understand the concepts of the disclosure and will recognize applications of these concepts that are not particularly addressed herein. These concepts and applications fall within the scope of the disclosure and the accompanying claims.

The above description and drawings are illustrative and are not to be construed as limiting. Numerous specific details are described to provide a thorough understanding of the disclosure. However, in certain instances, well-known details are not described in order to avoid obscuring the description. Further, various modifications may be made without deviating from the scope of the embodiments.

As used herein, unless specifically stated otherwise, terms such as “processing,” “computing,” “calculating,” “determining,” “generating,” or the like, refer to actions and processes of a computer or similar electronic computing device that manipulates and transforms data represented as physical (electronic) quantities within the computer's memory or registers into other data similarly represented as physical quantities within the computer's memory, registers, or other such storage medium, transmission, or display devices.

Reference herein to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not for other embodiments.

The terms used in this specification generally have their ordinary meanings in the art, within the context of the disclosure, and in the specific context where each term is used. Certain terms that are used to describe the disclosure are discussed above, or elsewhere in the specification, to provide additional guidance to the practitioner regarding the description of the disclosure. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that the same thing can be said in more than one way.

Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any term discussed herein is illustrative only and is not intended to further limit the scope and meaning of the disclosure or of any exemplified term. Likewise, the disclosure is not limited to various embodiments given in this specification.

Without intent to further limit the scope of the disclosure, examples of instruments, apparatus, methods and their related results according to the embodiments of the present disclosure are given above. Note that titles or subtitles may be used in the examples for convenience of a reader, which in no way should limit the scope of the disclosure. Unless otherwise defined, all technical and scientific terms used herein have the same meaning as commonly understood by one of ordinary skill in the art to which this disclosure pertains. In the case of conflict, the present document, including definitions will control.

From the foregoing, it will be appreciated that specific embodiments of the invention have been described herein for purposes of illustration, but that various modifications may be made without deviating from the scope of the invention. Accordingly, the invention is not limited except as by the appended claims.

1. A method for error checking in a wireless communication, the method comprising:
receiving a payload;
determining a final decoding result of the payload, wherein the final decoding result indicates a start state and an end state;
determining whether the end state is identical to the start state based on a state circularity check; and
determining to discard the final decoding result based on whether the end state is identical to the start state.

2. The method of claim 1, wherein determining the final decoding result further comprises:
decoding the payload according to Viterbi decoding techniques.

3. The method of claim 1, further comprising:
determining, according to the state circularity check, that the end state is not identical to the start state; and
discarding the final decoding result.

4. The method of claim 1, further comprising:
determining, according to the state circularity check, that the end state is identical to the start state; and
performing one or more error checks of the final decoding result.

5. The method of claim 4, wherein the payload includes one or more cyclic redundancy check (CRC) bits, and wherein the error check is a CRC.

6. The method of claim 5, further comprising:
determining, based on the CRC, that the end state is not identical to the start state; and
discarding the final decoding result.

7. The method of claim 4, wherein the error check is a path metric check.

8. The method of claim 7, further comprising:
determining, based on the path metric check, that a maximum state metric is smaller than a threshold value, wherein the maximum state metric is indicative of a number of states included in the final decoding result; and
discarding the final decoding result.

9. The method of claim 4, wherein the error check is a payload field validness check.

10. The method of claim 9, further comprising:
determining, based on the payload field validness check, that the payload includes an invalid field combination; and
discarding the final decoding result.

11. The method of claim 1, further comprising:
decoding the payload according to any of maximum a posteriori (MAP) techniques, logarithmic maximum a posteriori (LOG-MAP) techniques, maximum logarithmic maximum a posteriori (MAX-LOG-MAP) techniques, and/or soft output Viterbi algorithms (SOVA).

12. The method of claim 1, wherein the payload is received on any tail-biting coded channels.

13. A method comprising:
receiving a payload;
determining a final decoding result of the payload, wherein the final decoding result indicates a start state and an end state, and wherein determining the final decoding result further comprising: decoding the payload;
determining whether the end state is identical to the start state based on a state circularity check;
performing an error check of the final decoding result; and
determining to discard the final decoding result based on (1) whether the end state is identical to the start state or (2) the error check.

14. The method of claim 13, wherein decoding the payload comprises: decoding the payload according to Viterbi decoding techniques.

15. The method of claim 13, wherein the error check is any of a cyclic redundancy check (CRC), a path metric check, and/or a payload field validness check.

16. The method of claim 13, further comprising:
determining that the end state is not identical to the start state; and
discarding the final decoding result.

17. The method of claim 13, further comprising:
determining that the end state is identical to the start state; and
discarding the final decoding result based on the error check.

18. The method of claim 13, wherein performing the error check further comprises:
upon determining that the end state is identical to the start state, determining to perform the error check.

19. The method of claim 13, wherein the payload is received on a physical downlink control channel (PDCCH).

20. A system comprising:
a receiver operable to receive a payload;
a processor configured to:
determine a final decoding result of the payload, wherein the final decoding result indicates a start state and an end state;
determine whether the end state is identical to the start state based on a state circularity check; and
determine to discard the final decoding result based on whether the end state is identical to the start state.
